(19) United States
(12) Patent Application Publication
(10) Pub. No.: US 2009/0309615 A1
(43) Pub. Date: Dec. 17, 2009

(54) METHOD AND SENSOR ARRANGEMENT FOR MEASURING THE MIXING RATIO OF A MIXTURE OF SUBSTANCES

(76) Inventors: Norbert Reindl, Fuerstenzell (DE); Lothar Jayme, Karlsbad (DE)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 12/301,127

(22) PCT Filed: May 9, 2007
(86) PCT No.: PCT/DE2007/000858

§ 371 Date: Nov. 17, 2008

(30) Foreign Application Priority Data
May 19, 2006 (DE) 102006023942.3
Dec. 1, 2006 (DE) 102006057136.3

(51) Int. Cl. G01R 27/26

(52) U.S. Cl. 324/684

(57) ABSTRACT

As regards a measurement structure which is as simple as possible and in order to influence the mixing operation or the transfer of substances to the slightest possible extent, a method for measuring the mixing ratio of a mixture of substances comprising at least two substances (10, 11) is configured in such a manner that the mixture of substances is brought into the measurement range of a capacitive sensor (1)—in particular is moved past the latter or moved through the latter—and the mixing ratio is determined from the change in the capacitance of the sensor (1), which change is caused by the mixture of substances. A corresponding sensor arrangement in which the mixture of substances is guided through a tubular area (2) is specified.

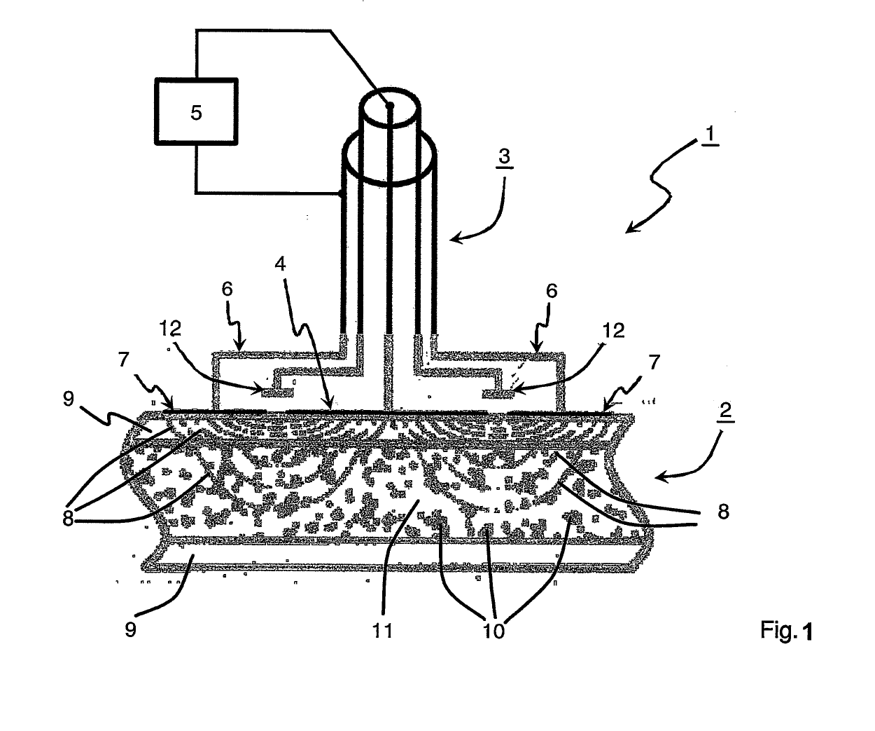

The invention relates to a method for measuring the mixture ratios of a mixture of substances comprising at least two substances. Further, the invention relates to a respective sensor arrangement, with the substance mixture being guided through a tubular section.

In technology, there is the need in various applications to determine the mixture ratio of substances of mixtures of substances. For example, in sand blasting it is interesting to obtain the percentage by volume of sand particles contained in the air jet. Similarly, in (water) jet cutting more precise information is necessary concerning the particle content in the water jet in order to optimally control the quality of the cutting process. Here, solid particles are included in a flow of gaseous or liquid substances. However, mixtures of substances can also be formed by several solid substances.

For example, measurements can already be taken during the production of the mixture of substances in order to determine the mixture ratio. For example, in a water/sand mixture the throughput of the water and simultaneously the sand mixed therein can be determined. This way, the mixture ratio can be determined comparatively easily. However, this method has the decisive disadvantage that at any time the precise amount of the substances actually mixed must be known. Frequently this can be realized only with a relatively large expense or comparatively imprecisely. Additionally, it can only be applied in substances provided separately. The mixture ratio of prefabricated mixtures of substances cannot be determined this way.

The present invention is therefore based on the object to provide and further develop a method and a sensor arrangement of the type mentioned at the outset such that the mixture ratio of a mixture of substances can be determined cost-effectively and with simple means. Here, the mixing process and/or the transportation of the mixture of substances shall be interfered with as little as possible.

According to the invention the above-mentioned object is attained in the features of claim 1. Here, the method in question is characterized in that the mixture of substances is brought into the measuring range of a capacitive sensor, particularly moving past it or through it, and that the mixture ratio is determined from the change of the capacity of the sensor caused by the mixture of substances.

First, it has been recognized in an inventive manner that for the measurement of mixture ratios in a most simple fashion the material properties of the substances in a mixture of substances can be used. Individual material properties are suitable to be detected by electric or electromagnetic fields. Such fields can be created by capacitive sensors and the effects of the material properties on the sensor can directly be measured. Therefore, individual substances can be distinguished by the use of a capacitive sensor. Here, it is utilized that individual substances influence the capacity of the sensor to a different extent when they are brought into its measuring range. According to the invention, precisely this effect can also be used for the determination of the mixture ratios. Similar to individual substances, a mixture of substances also leads to an influence on the capacity of the sensor in the measuring range of a capacitive sensor. However, this effect yields totals, i.e., the influence of the entire mixture of substances is detected in the measuring range of the sensor. The effects of an individual substance cannot be determined. However, this information can still be used according to the invention. When the composition of the mixture of substances is essentially known with regard to the substances contained, the mixture ratio can be concluded from the summarized influence of the mixture of substances.

Here, the composition of the substance is irrelevant, in principle. For example, the mixture of substances can be formed by several substances. However, the mixture of substances examined may in turn comprise other mixtures of substances. This is the case, for example, when the mixture ratio of granulate in an air flow shall be determined, with said granulate being formed by a mixture of substances. Here, it is generally only important to know the voluminous ratio of granulate versus air, i.e., a mixture of substances in reference to one other substance. For the determination of the mixture ratio according to the invention it is conditional only that the substances or mixtures of substances sufficiently differ with regard to the examined material properties and that the examined material properties remain sufficiently constant during measuring. Additionally, the mixture of substances shall be of sufficient homogeneity. When the mixture ratio in the measuring range of the sensor excessively depends on the position during measuring, the result yielded may not be sufficiently meaningful, perhaps.

This knowledge according to the invention is used in the method such that the mixture of substances to be examined is brought into the measuring range of the capacitive sensor. Here it is irrelevant, in principle, if the mixture of substances remains stationary or is mobile during the measurement. In most applications the mixture of substances will be moved passing or through the sensor, though. The mixture of substances in the measuring range of the sensor changes its capacity. This change, in addition to the knowledge of the mixture or mixtures of substances contained and their respective material properties, allow conclusions on the mixture ratio.

In general, not all substances contained in a mixture of substances or substance mixtures have to be known precisely. It is only relevant that information concerning the components is available having essential influence on the capacity of the sensor. For example, when the method is applied in the context of sand blasting the sand/air mixture may contain traces of a metal that was abraded from a work piece in a (prior) blasting process. This may occur when the sand is used repeatedly. In this case it is important that the additional particles are of little influence on the capacity of the sensor in reference to the other components of the mixture of substances. In a preferred embodiment the permittivity of the mixture of substances is used as the material property. The permittivity is a physical variable showing the permeability of matter for electric fields. This effect appears in non-conductive and semi-conductive substances. When such a material is brought into the range of a condenser and/or a capacitive sensor, an increase in capacity can be detected. Therefore, the capacity of the sensor increases when a mixture of substances comprising such materials is brought into the measuring range of a capacitive sensor.

The determination of the mixture ratio is thus concluded from the determination of the capacity of the sensor. All methods known from practice are available for the determination of the capacity. The measured or otherwise determined capacity of the sensor is subsequently compared to a reference value. This reference value generally represents the capacity of the sensor without being influenced by the mixture of substances. This way, the extent of the increase or reduction of the capacity can be concluded.

With regard to a measurement as precise as possible, a correction of measuring errors could be performed prior to the execution of the comparison of the capacity measured and the reference value. This correction particularly comprises the correction of systematic errors. For example, when guiding the mixture of substances in a hose the capacity of the sensor is already influenced by the permittivity of said hose. It increases the capacity of the sensor without any influence by the mixture of substances. Such errors could be compensated.

In order to determine a reference value at least one calibration measurement could be performed. This way the capacity of the sensor can be detected metrologically. Here, a sensor parameter could also be recorded, for example reflecting the behavior of the sensor on food signals having different frequencies and/or amplitudes. The calibration measurements could be performed on the one hand with a sensor when being in a neutral environment, i.e., without any influence by other substances. Alternatively or additionally the capacity of the sensor could be determined in its operating environment. This could avoid some of the corrections of measuring errors otherwise perhaps necessary for measurements.

However, the reference value could also be calculated. Here, several methods are known in prior art, by which the capacity of a relatively arbitrary conductive structure can be calculated. The calculation is differently complex depending on the complexity of the sensor used. In some cases simple approximations can be found, for example in case of a sensor comprising two parallel plates. In other cases, more complex calculations are necessary. Here, suitable methods are known in prior art.

The comparison of the capacity of the sensor measured in operation with the reference value results in the level of the influence of the mixture of substances on the capacity of the sensor. When additional information is used concerning the components of the mixture of substances, conclusions can be drawn on the mixture ratio of the mixture of the substances using a mathematical model. The selection and the design of the mathematical model will depend on the respective application. Such models are sufficiently known in practice. As an alternative to the use of a mathematical model, the allocations of measurements to a mixture ratio can also occur based on measurement values determined in a different context or the like.

When only measurements with constant parameters are performed, only two components of the mixture of substances can be distinguished. When more than two components shall be examined with regard to their mixture ratio, several measurements with different framework conditions can be performed. This can be achieved, for example, in that other material parameters are used. However, it is always conditional that they can be calculated unambiguously from the capacity measured.

The capacitive sensor is advantageously fed with direct and/or alternating current during the determination of its capacity. When the sensor is supplied with direct current, deviations in the mixture ratio can easily be detected. In the static condition, no or at the most a negligible current flows when direct current is given. However, compensation currents flow that can be detected when the capacity of the sensor changes. Measuring the compensation current therefore allows conclusions on the change of the capacity. Since all components potentially influencing the capacity of the sensor will be constant except for the permittivity of the mixture of substances, in this way the change in the mixture of substances can be determined.

The supply of the sensor with alternating current can determine the impedance of the sensor. The frequency is selected depending on the design of the sensor used, the mixture of substances to be examined, and/or other framework conditions. Methods to determine the impedance and to select a suitable frequency are known from prior art. Here, the use of measurements of various frequencies is also possible.

In addition to the use of direct or alternating current, a superimposition of a direct current with an alternating current may be useful as well.

In addition to the possible adjustment of the frequency of the supply voltage for the sensor, the ability to adjust the amplitude may be provided. By adjusting the amplitude the non-linearity of various materials in different strong fields could be used.

The selection of the measuring method will depend on the mixture of substances to be examined. When it is known that only two substances are included in a mixture of substances, any capacity measurement incited by a relatively low-frequency alternating current will be sufficient. When however a mixture comprising several substances, for example sand and polyethylene in a water jet, shall be detected, measurements with several different frequencies can be performed in order to determine the individual components in their mixture ratios.

For a control of the measuring process as flexible as possible, means could be provided by which the depth of penetration of the field created by the sensor is influenced. For example, the level of the influence of the mixture of substances on the capacity of the sensor can be influenced. The farther the field penetrates the mixture of substances the higher the detectable effect of the mixture on the capacity. However, limits are set here, for example, in that the dampening in the mixture of substances can lead to higher penetration depths not leading to any further measuring effect.

With regard to a sensor arrangement, the above-mentioned object is attained in the features of claim 13. Accordingly, the sensor arrangement in question is embodied such that a tubular area, through which the mixture of substances is guided, is located within the measuring range of a capacitive sensor detecting the changes of its capacity caused by the mixture of substances. This sensor arrangement is particularly suitable for the application of the method according to the invention.

The term “tubular area” is to be understood in a general way. For example, this area may actually refer to a tube embodied from the most different materials and in the most different manner. However, the tubular area may also be formed by other embodiments known in practice. It is only conditional that the mixture of substances can be guided through the arrangement used. Here, the sensor itself can be used to guide the mixture of substances so that the mixture of substances comes into a direct contact to the sensor. Here, the sensor itself is a part of the tubular area. When the sensor is only placed onto the tubular area the material encircling the tubular area must be suitable for penetration by electric fields. Finally, the tubular area must be suitable to limit a defined area that can be detected by the measuring range of the sensor.

The sensor arrangement is provided with at least two electrodes. At least one electrode is embodied as a measuring electrode that can be impinged with a measuring signal. Furthermore, at least one electrode should be provided suitable as a counter electrode of the measuring electrode. In a preferred embodiment the counter electrode is embodied as a part of the shield, preferably as its particularly embodied end section. The object of the shield is here, on the one hand, to form a flux line between the measuring electrode and the shield. Furthermore, the shield can be used to allow a certain shielding from interspersed electric or electromagnetic fields. For this purpose, the shield preferably encircles the measuring electrode at several sides.

Further, the sensor could be provided with a control electrode, controlling the extent of the measuring range of the sensor. This can be realized, on the one hand, in modifying the effective distance between the measuring electrode and the counter electrode. For this purpose, the control electrode could be embodied in different widths. The extent of the measuring range is therefore already predetermined at the production of the sensor. Depending on the desired range, differently embodied sensors could then be used. Alternatively or additionally the control electrode could be impinged with a voltage leading to the formation of an electric or electromagnetic field. This field can be embodied such that it influences the field embodied between the measuring electrode and the counter electrode. The influence would show in the actual measuring field projecting to a different extent into the range prior to the sensor. In extreme cases, the electric field can even exceed the tubular area.

In one embodiment of the invention the sensor is placed onto the tubular area. Here, the sensor could be adhered to the tubular area or connected thereto in a different way. Particularly for achieving a form-fitting contact between the sensor and the tubular area the sensor could be pressed onto the tubular area. This could lead to a deformation of the area, depending on the constitution of the material forming the tubular area. A plate could be arranged at the side of the tubular area opposite the sensor as a counter bearing. This plate can be formed, on the one hand, from a non-conductive material, such as plastic, on the other hand, conductive materials can be used, for example, steel.

In another embodiment of the sensor arrangement the sensor is embodied such that it encompasses the tubular area at least partially. This could be achieved, for example, such that circular electrodes encompass the tubular area. This way, a particularly effective measurement of the mixture of substances contained in the tubular area can be achieved.

A particularly simple embodiment comprises a measuring electrode with a counter electrode being allocated opposite at a fixed distance. The electrodes could be embodied similar to plate condensers. The mixture of substances is located between the electrodes or is made to pass between them. To shield from interspersed noise fields a shield could be provided around the arrangement.

Depending on the embodiment of the tubular area and depending on the desired application one or the other embodiment of the sensor could prove more suitable. Furthermore, additional embodiments of capacitive sensors can be used.

For operation a supply unit is connected to the sensor. This supply unit could create a supply voltage for the sensor. Direct current or alternating current is suitable as the supply voltage. However, a supply voltage can also be used representing a superposition of direct current and alternating current.

In order to achieve a measurement as flexible as possible the supply voltage can be adjustable with regard to its amplitude and/or frequency. When the supply voltage is changed, a one-time increase of the voltage could be provided from one value to a second value. The increase can occur linearly in the form of one or several steps, or in a different way. Repeated, for example, periodic changes are also possible. A reduction can also be used instead of increasing the values. Here, the application again decides if a change is necessary and how to embody it.

A device is provided for evaluating the changed capacity, by which the capacity and/or the change of the capacity of the sensor can be detected. This can occur by current measuring devices, analog-digital converters, and/or other devices known in practice. Additionally, an evaluation electronic shall be provided to process the measured capacity of the sensor. For this purpose, again all methods are available known in prior art. Due to its very comprehensive and flexible utilization the evaluation electronic preferably comprises a micro-computer with an allocated circuitry including one or more analog-digital converters.

Now, there are various possibilities to advantageously embody and further develop the teaching of the present invention. For this purpose, reference is made, on the one hand, to the claims dependent on claims 1 and 13, and on the other hand, to the following description of a preferred exemplary embodiment of the invention using the drawing. In connection to the description of the preferred embodiment of the invention using the drawing, the preferred embodiments and further developments of the teaching are also explained in general. In the drawing the only figure shows in a schematic representation, the design of a sensor arrangement according to the invention in principle.

The sole FIGURE shows schematically the design of a sensor arrangement in principle. A sensor 1 is placed onto a tubular area 2. The sensor 1 comprises a connection area 3 and different electrodes 4, 7, 12. These electrodes comprise a measuring electrode 4 via a generator 5 impinged with an alternating current. The measuring electrode 4 is encompassed by a shield 6. Here, the measuring electrode 4 is openly accessible in the direction of the tubular area 2 only. One end of the shield 6 converts into the connection area 3, the other end is embodied as the counter electrode 7 following the measuring electrode 4 left and right in the figure. This way, the shield 6 serves, on the one hand, to form a counter electrode 7 for the measuring electrode 4, on the other hand, it is embodied as a shield of the connection line between the generator 6 and the measuring electrode 4. Thus, the shield 6 is suitable to shield the signal guided to the measuring electrode 4 from exterior influences.

When the electrodes 4, 7 are impinged with voltage, electric flux lines 8 form between the measuring electrode 4 and the counter electrode 7. These flux lines 8 first penetrate the material 9, here plastic, encompassing the tubular area 2. Some of the flux lines 8 directly lead from the measuring electrode 4 to the counter electrode 7 in the material 9 and do not enter the tubular area 2. This portion is constant and must be suitably compensated in an evaluation electronic or already be considered in calibration measurements. However, some of the flux lines 8 leave the material 9 and penetrate the interior of the tubular area 2. This portion represents the actually measurement-relevant part of the field. These flux lines are influenced by the mixture of substances located in the tubular area. In this case, the mixture of substances comprises grains of sand 10, located in a flow of air 11 and guided in the tubular area 2. The mixture can be mixed with water in a subsequent step and be used for water jet cutting. Similarly, the air/sand mixture can also be used in sand blasting booths. The sand portion typically ranges from 1-10% by volume. Depending on the mixture ratio between sand 10 and air 11, this leads to differently strong influences on the capacity of the sensor 1.

In order to calculate the mixture ratio, several parts of the capacity of the sensor must be considered. The total capacity comprises approximately a combined serial and parallel circuit of individual capacities. A portion is formed by a part of the flux lines 8, directly formed between the measurement electrode 4 and the counter electrode 7 in the material 9. Another partial capacity comprises the flux lines 8 first penetrating through the material 9 into the tubular area 2 and leaving it again via the material 9. For this part of the flux lines 8 therefore a dielectric comprising three layers must be considered and an approximated capacity of

$$C = \frac{{ɛ}_{0} \cdot A}{\frac{{d}_{1}}{{ɛ}_{1}} + \frac{2 {d}_{2}}{{ɛ}_{2}}}$$

can be calculated. Here, the characters of the formula represent the following: A area, d, average field length in the mixture, ε₁ rel. permittivity of the mixture, d₂ wall thickness of the tube, and ε₂ rel. permittivity of the tube. Due to the fact that all parameters except for ε₁ are constant, a dependency of the total capacity of the mixture can be determined. This can be used in a subsequent processing electronic, not shown, to yield conclusions on the mixture ratio of the mixture of substances guided inside the tubular area 2.

Depending on the design of the sensor arrangement, particularly the tubular area 2, the flux lines 8 penetrate the tubular area 2 to a different extent. Therefore another electrode 12 of the sensor 1 is provided to control the depth of penetration of the electric field. The electrode 12 is embodied such that the width of the electrode is approximately equivalent to the distance of the electrodes 4 and 7 in reference to each other. Additionally the electrode 12 is impinged with a voltage causing a potential to force the flux lines 8 to penetrate the tubular area 2 more or less strongly between the measuring electrode 4 and the counter electrode 7. In a possible type of impingement of the electrode 12 a potential is created equivalent to the potential of the electrode 4. This way, the part of the electric field penetrating the tubular area 2 can be controlled depending on the embodiment of the tubular area 2 and depending on the desired requirements.

Finally, it shall be particularly emphasized that the above-mentioned exemplary embodiment has been randomly selected for describing the teaching according to the invention without any limitations to said exemplary embodiment.

1.-25. (canceled)

26. A method for measurement of mixing ratio of a substance mixture of at least two substances, wherein the substance mixture is brought into the measurement range of a capacitive sensor, especially moved past or through it, and wherein the mixing ratio is determined from the change in capacitance of the sensor caused by the substance mixture.

27. A method according to claim 26, wherein the permittivity of the components of the substance mixture is used as characteristic for measurement of the mixing ratio.

28. The method according to claim 26, wherein the capacitance of the sensor is determined and compared to a reference value that indicates the capacitance of the sensor without the influence from the substance mixture, in which
a correction of measurement errors, especially systematic errors, can be made before the comparison and/or in which
at least one calibration measurement can be conducted to obtain the reference value and/or in which
the reference value can be calculated.

29. The method according to claim 28, wherein the permittivity of the substance mixture is determined by the comparison, in which
the ratio of one substance or substance mixture to another substance or substance mixture can be determined from the permittivity of the substance mixture, in which the permittivities of the individual substances and/or substance mixtures are preferably known.

30. The method according to claim 26, wherein additional material characteristics are used to determine the mixing ratio.

31. The method according to claim 26, wherein the sensor is supplied with DC voltage and/or AC voltage, in which measurements can be conducted with different amplitudes and/or frequencies of the supply voltage of the sensor.

32. The method according to claim 26, wherein the penetration depth of the electric field is controlled to vary the measurement range of sensor.

33. A sensor arrangement for measurement of the mixing ratio of a substance mixture of at least two substances, especially for use of a method according to claim 26, in which the substance mixture is passed through a tube-like area, wherein the tube-like area is situated in the measurement range of a capacitive sensor, which records the change of its capacitance caused by the substance mixture.

34. The sensor arrangement according to claim 33, wherein the sensor has at least two electrodes, in which the electrodes can have a measurement electrode.

35. The sensor arrangement according to claim 34, wherein the electrode is designed in the form of a screen and/or wherein the screen encloses the measurement electrode on several sides and/or wherein an electrode is provided with which the measurement range of the sensor can be controlled.

36. The sensor arrangement according to claim 33, wherein the sensor is mounted on the tube-like area and/or is pressed onto the tube-like area so that the area is deformed.

37. The sensor arrangement according to claim 36, wherein a plate is arranged as abutment on the side of the tube-like area opposite the sensor.

38. The sensor arrangement according to claim 33, wherein the sensor at least partially encloses the tube-like area.

39. The sensor arrangement according to claim 33, wherein a DC voltage and/or AC voltage can be generated as supply voltage for the sensor, in which the supply voltage can be varied in its amplitude and/or frequency.

40. The sensor arrangement according to claim 33, wherein means are provided with which the capacitance of the sensor can be recorded and/or evaluated.
